(19) United States
(12) Patent Application Publication
(10) Pub. No.: US 2014/0165914 A1
(43) Pub. Date: Jun. 19, 2014

(54) ORGANIC MATERIAL DEPOSITION APPARATUS

(71) Applicant: Samsung Display Co., Ltd., Yongin-City (KR)

(72) Inventor: Jae-Cheol Lee, Yongin-City (KR)

(21) Appl. No.: 14/070,983

(22) Filed: Nov. 4, 2013

(30) Foreign Application Priority Data
Dec. 14, 2012 (KR) 10-2012-0146634

(51) Int. Cl. C23C 16/44

(52) U.S. Cl. CPC C23C 16/4401
USPC 118/724

(57) ABSTRACT

An organic material deposition apparatus includes a chamber, a substrate support unit, a rail, a driving apparatus, a plate heating apparatus, and a plate cooling apparatus. The substrate support unit is disposed in an upper portion of the chamber and supports the substrate. The rail extends from a deposition region, which is disposed under the substrate support unit, to a standby region. The driving apparatus moves a crucible which evaporates an organic material. The plate heating apparatus heats an upper plate disposed in an upper portion of the standby region. The plate cooling apparatus cools a lower plate disposed in a lower portion of the standby region.

### CLAIM OF PRIORITY

This application claims the benefit of Korean Patent Application No. 10-2012-0146634, filed on Dec. 14, 2012, in the Korean Intellectual Property Office, the disclosure of which is incorporated herein in its entirety by reference.

### BACKGROUND OF THE INVENTION

1. Field of the Invention

Aspects of the present invention relate to organic material deposition apparatuses, and more particularly, to an organic material deposition apparatus capable of minimizing internal contamination.

2. Description of the Related Art

Organic light emitting display apparatuses are self-emitting display apparatuses that include an organic light emitting device, the organic light emitting device including a hole implantation electrode, an electron implantation electrode, and an organic emission layer. In the self-emitting display apparatuses, light is generated while exciton produced due to a combination of a hole implanted by the hole implantation electrode with an electron implanted by the electron implantation electrode within the organic emission layer is falling from an excited state to a ground state.

Organic light emitting display apparatuses as self-emitting display apparatuses are capable of operating at a low voltage and becoming light and thin, because no special light sources are necessary, and are highlighted as a next generation display device due to its advantages such as a wide viewing angle, a good contrast, and a fast response speed.

However, since organic light emitting display apparatuses are degraded due to external moisture, oxygen, or the like, they seal an organic light emitting device to protect the organic light emitting device from the external moisture, oxygen, or the like.

To obtain thin and/or flexible organic light emitting display apparatuses, thin film encapsulation (TFE) formed of a plurality of thin films including a plurality of organic layers and a plurality of inorganic layers is used to seal an organic light emitting device included in the thin and/or flexible organic light emitting display apparatuses. The organic layers of the TFE may be formed by using an organic material deposition apparatus.

In conventional organic material deposition apparatuses, an organic material deposition source is fixed, and an organic material is deposited on a substrate while a mask and the substrate are passing over the organic material deposition source. Even when the substrate does not exist on the organic material deposition source, the organic material is continuously emitted and deposited on an inner wall of the conventional organic material deposition apparatuses. This may cause the conventional organic material deposition apparatuses to be contaminated.

### SUMMARY OF THE INVENTION

The present invention provides an organic material deposition apparatus capable of minimizing internal contamination.

According to an aspect of the inventive concept, there is provided an organic material deposition apparatus including a chamber including a deposition region and a standby region, a substrate support unit, a rail, a driving apparatus, a plate heating apparatus, and a plate cooling apparatus. The substrate support unit accommodated in an upper portion of the chamber and supports the substrate. The rail extends from a deposition region, which is disposed under the substrate support unit, to a standby region. The driving apparatus moves a crucible, which evaporates an organic material, along the rail. The plate heating apparatus heats an upper plate disposed in an upper portion of the standby region. The plate cooling apparatus cools a lower plate disposed in a lower portion of the standby region.

The plate cooling apparatus may cool a lateral plate disposed on at least three lateral sides of the standby region.

The lower plate may extend to the deposition region so as to be disposed in at least a part of a lower portion of the deposition region.

The chamber may comprise a chamber barrier wall that separates an upper region, in which the substrate support unit is disposed, from a lower region including the deposition region and the standby region. The chamber barrier wall may comprise an opening portion under the substrate support unit.

A mask may be mounted on a circumference of the opening portion via an o-ring. A space between the chamber barrier wall and the mask may be sealed.

The chamber may further comprise a chamber outer wall that surrounds the upper region and the lower region. The chamber barrier wall may be fixed to the chamber outer wall so that a space between the chamber barrier wall and the chamber outer wall is sealed.

The organic material deposition apparatus may further comprise a chamber heating apparatus which heats at least one of the chamber outer wall and the chamber barrier wall.

The organic material deposition apparatus may further comprise a rail heating apparatus which heats the rail.

The substrate support unit may further comprise a substrate cooling apparatus which cools the substrate.

The organic material deposition apparatus may further comprise a hardening lamp which is moved together with the crucible along the rail.

The plate heating apparatus may increase a temperature of the upper plate to a temperature equal to or higher than a boiling point of the organic material.

The plate cooling apparatus may decrease a temperature of the lower plate to a temperature lower than or equal to a freezing point of the organic material.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic sectional view of an organic material deposition apparatus according to an embodiment of the present invention as viewed in one direction;

FIG. 2 is a schematic sectional view of the organic material deposition apparatus of FIG. 1 as viewed in another direction;

FIG. 3 is a sectional view conceptually illustrating a second region illustrated in FIG. 2;

FIG. 4 is a perspective view of an upper plate, a lower plate, and a lateral plate according to an embodiment of the present invention which may be included in the organic material deposition apparatus illustrated in FIG. 1;

FIG. 5 is a perspective view of an upper plate, a lower plate, and a lateral plate according to another embodiment of the present invention which may be included in the organic material deposition apparatus illustrated in FIG. 1;

FIG. 6 is a schematic sectional view of an organic light-emitting display apparatus fabricated by using the organic material deposition apparatus illustrated in FIG. 1, according to an embodiment of the present invention; and

FIG. 7 is a magnified view of a portion F illustrated in FIG. 6.

### DETAILED DESCRIPTION OF THE EMBODIMENTS

Hereinafter, the present invention will be described more fully with reference to the accompanying drawings, in which exemplary embodiments of the invention are shown. These embodiments are provided so that this disclosure will be thorough and complete, and will fully convey the scope of the present invention to one of ordinary skill in the art. This invention may, however, be embodied in many different forms and should not be construed as limited to the exemplary embodiments set forth herein, and it is to be appreciated that all changes, equivalents, and substitutes that do not depart from the spirit and technical scope of the present invention are encompassed in the present invention.

In the drawings, like reference numerals denote like elements, and the sizes or thicknesses of elements may be exaggerated for clarity of explanation.

The terms used in the present specification are merely used to describe particular embodiments, and are not intended to limit the present invention. An expression used in the singular encompasses the expression in the plural, unless it has a clearly different meaning in the context. It will be further understood that the terms “comprises” and/or “comprising,” or “includes” and/or “including” when used in this specification, specify the presence of stated features, but do not preclude the presence or addition of one or more other features. As used herein, the term “and/or” includes any and all combinations of one or more of the associated listed items. It will be understood that, although the terms first, second, third, etc., may be used herein to describe various features, these features should not be limited by these terms. These terms are only used to distinguish one feature from another feature. When a first feature is referred to as being “connected” or “coupled” to a second feature, it can be directly connected or coupled to the second feature or a third feature may intervene between the first and second features. When a first element is referred to as being “on” a second element, the first element can be directly on the second element or a third element may intervene between the first and second elements. In contrast, when a first element is referred to as being “directly on” a second element, there are no intervening elements present.

Unless defined differently, all terms used in the description including technical and scientific terms have the same meaning as generally understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Expressions such as “at least one of,” when preceding a list of elements, modify the entire list of elements and do not modify the individual elements of the list.

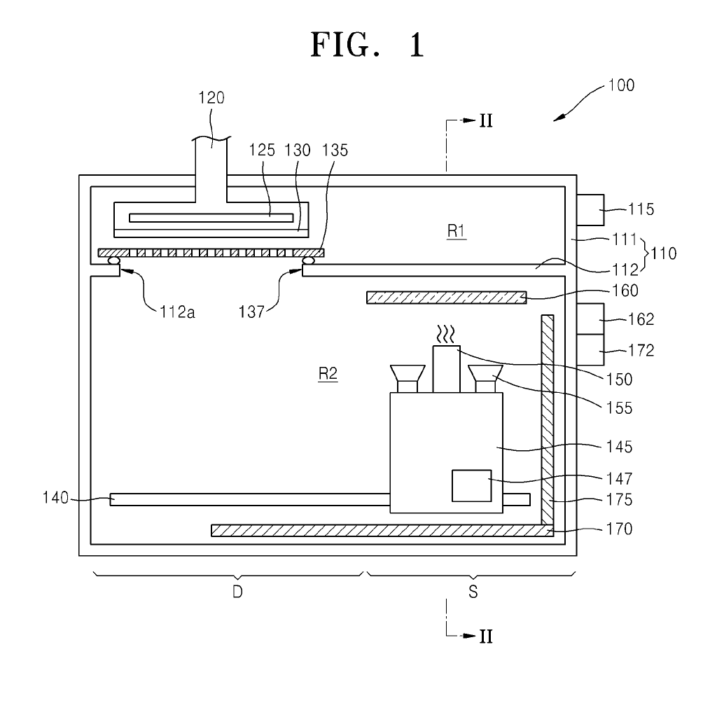

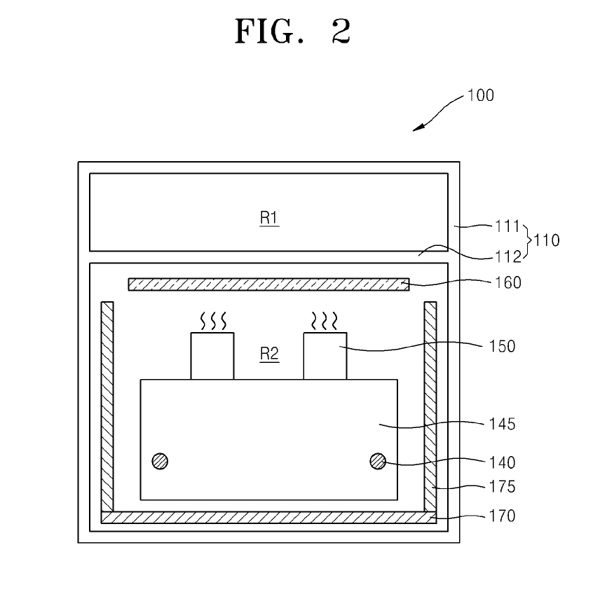

FIG. 1 is a schematic sectional view of an organic material deposition apparatus 100 according to an embodiment of the present invention as viewed in one direction. FIG. 2 is a schematic sectional view of the organic material deposition apparatus 100 of FIG. 1 as viewed in another direction. In detail, FIG. 2 is a schematic sectional view taken along line II-II of FIG. 1.

Referring to FIGS. 1 and 2, the organic material deposition apparatus 100 includes a chamber 110, which includes an outer wall 111 and an inner barrier wall 112.

The chamber 110 is a space where organic material deposition occurs, and exhaust means such as a vacuum pump (not shown) may be connected to the chamber 110 in order to control a process atmosphere. The chamber 110 may accommodate a substrate support unit 120 for supporting a substrate 130, a mask 135, and a crucible 150 from which an organic material is evaporated, and may protect them. Although not illustrated in FIGS. 1 and 2, the chamber 110 may include at least one entrance via which the substrate 130 and the crucible 150 enter.

The chamber 110 may include a first region R1 and a second region R2, which are spatially separated by the inner barrier wall 112. The first region R1 is a region in which the substrate 130 is located, and may be referred to as an upper region. The second region R2 is a region in which the crucible 150 containing an organic material to be deposited is located, and may be referred to as a lower region.

The second region R2 may be divided into a standby region S and a deposition region D. In the standby region S, the crucible 150 stands by until the organic material starts being stably evaporated. In the deposition region D, the organic material is deposited on the substrate 130. The deposition region D may denote a region under the substrate support unit 120.

The outer wall 111 may be referred to as a wall that surrounds the first region R1 and the second region R2. As described above, an entrance may be formed in the outer wall 111, and a vacuum pump may be installed on the outer wall 111.

The inner barrier wall 112 may be fixed to the outer wall 111. For example, the inner barrier wall 112 may be integrally formed with the outer wall 111. A space between the inner barrier wall 112 and the outer wall 111 may be sealed. Consequently, the first region R1 and the second region R2 may be completely spatially separated from each other. In other words, a contamination source generated in the second region R2 may not be transferred to the first region R1.

The inner barrier wall 112 may include an opening portion 112a formed under the substrate support unit 120. The opening portion 112a may be covered by the mask 135. Accordingly, when the crucible 150 is situated in the deposition region D, the organic material may be selectively deposited on the substrate 130 via the mask 135.

The mask 135 may be mounted on a portion of the inner barrier wall 112 around the opening portion 112a. The mask 135 may be fixed to the inner barrier wall 112 by using an O-ring 137, and a space between the mask 135 and the inner barrier wall 112 may be sealed. Consequently, the contamination source generated in the second region R2 may not be transferred to the first region R1 without passing through a plurality of slits of the mask 135.

The substrate support unit 120 may be disposed in the first region R1. The substrate support unit 120 may support the substrate 130. The substrate support unit 120 may align the substrate 130 and the mask 135. The substrate support unit 120 may include a substrate cooling apparatus 125 for cooling the substrate 130. The substrate cooling apparatus 125 may include a cooling device and a cooling plate connected to the cooling device. The cooling device may circulate a cooling fluid in the cooling plate, and the cooling plate may include a pipe in which the cooling fluid can flow.

The substrate cooling apparatus 125 may increase the percentage of an organic material evaporated from the crucible 150 that is deposited on the substrate 130, by decreasing the temperature of the substrate 130. Consequently, consumption of the organic material may be reduced.

The chamber 110 may further include a chamber heating apparatus 115, which heats the chamber 110. The chamber heating apparatus 115 may control the internal temperature of the chamber 110. The chamber heating apparatus 115 may heat the outer wall 111 and the inner barrier wall 112 of the chamber 110. Consequently, the organic material evaporated from the crucible 150 may be prevented from being deposited on the outer wall 111 and the inner barrier wall 112. The chamber heating apparatus 115 may heat only one of the outer wall 111 and the inner barrier wall 112.

In the second region R2, a rail 140 extending between the standby region S and the deposition region D may be disposed. A driving apparatus 145 for moving the crucible 150 along the rail 140 may be disposed on the rail 140. The crucible 150 may be disposed on the driving apparatus 145. The crucible 150 may be moved between the standby region S and the deposition region D along the rail 140 by the driving apparatus 145. As described above, the crucible 150 may stand by in the standby region S until it is ready to stably evaporate the organic material. When the organic material is stably evaporated, the crucible 150 may move into the deposition region D and thus deposit the organic material on the substrate 130.

The rail 140 may have a stick shape. Although the rail 140 has a circular cross-section in FIG. 2, this is only an example, and the rail 140 may have other shapes of cross-sections, for example, a rectangular cross-section and a square cross-section.

The driving apparatus 145 may include a rail heating apparatus 147. The rail heating apparatus 147 may heat the rail 140. As the rail 140 is heated, the organic material may be prevented from being deposited on the rail 140. The rail 140 may be heated to a temperature higher than the boiling point of the organic material.

The crucible 150 may contain an organic material. The crucible 150 may further include an organic material heating portion (not shown) for evaporating the organic material. The organic material heating portion heats the organic material to a temperature higher than the boiling point thereof and thus evaporates the organic material. The organic material may be hardened by ultraviolet rays. Hardening lamps 155 may be disposed adjacent to the crucible 150. The hardening lamps 155 may be disposed on the driving apparatus 145 and may be moved between the deposition region D and the standby region S together with the crucible 150 by the driving apparatus 145.

An upper plate 160 may be disposed in an upper portion of the standby region S. The upper plate 160 may be heated by a plate heating apparatus 162. The upper plate 160 may be heated to at least the boiling point of the organic material. The upper plate 160 may be heated to a temperature higher than the boiling point of the organic material. The upper plate 160 may be installed on the internal barrier wall 112. When the upper plate 160 is heated to the temperature higher than the boiling point of the organic material, an organic material vapor evaporated from the crucible 150 may not be deposited on the upper plate 160. The organic material vapor moves horizontally along the upper plate 160, and may fall down due to, for example, an internal air current.

A lower plate 170 may be disposed in a lower portion of the standby region S. A lateral plate 175 may be disposed on each lateral side of the standby region S except one lateral side. The lateral plate 175 may not be disposed on one lateral side of the standby region S, through which the standby region S and the deposition region D are connected, so that the crucible 150 and the driving apparatus 145 may move toward the deposition region D from the standby region S. The lower plate 170 may be cooled off by a plate cooling apparatus 172. The lateral plates 175 may also be cooled off by the plate cooling apparatus 172. The lower plate 170 and the lateral plates 175 may be cooled to at least the freezing point of the organic material. The lower plate 170 and the lateral plates 175 may be cooled to a temperature lower than the freezing point of the organic material. The lower plate 170 and the lateral plate 175 may be installed on the outer wall 111 of the chamber 110.

As the lower plate 170 and the lateral plates 175 are cooled to the temperature lower than the freezing point of the organic material, the organic material vapor may be collected by the lower plate 170 and the lateral plates 175. The plate cooling apparatus 172 may include a cryo-cooling pump. The lower plate 170 and the lateral plates 175 may be cooled to an extremely low temperature. Alternatively, the plate cooling apparatus 172 may include a chiller. A fluid cooled by the chiller may flow via pipes formed in the lower plate 170 and the lateral plates 175.

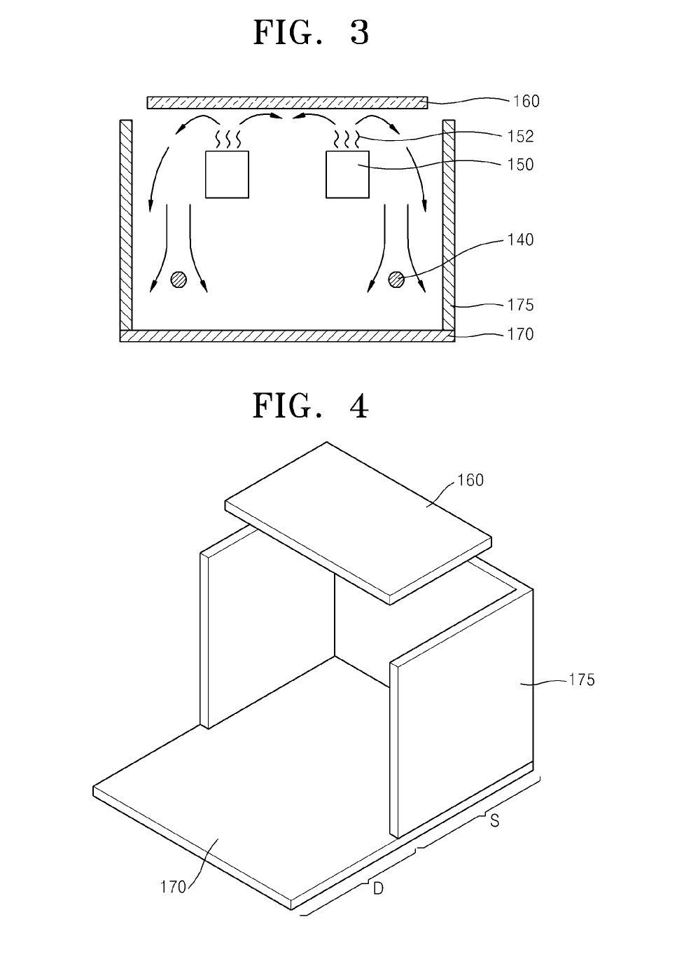

FIG. 3 is a sectional view conceptually illustrating the second region R2 illustrated in FIG. 2.

Referring to FIGS. 1 through 3, the crucible 150 may be located in the standby region S by the driving apparatus 145. The crucible 150 may heat the organic material included therein, until the organic material starts being stably evaporated, that is, until a certain amount of an organic material is evaporated. The organic material may be in a liquid state, and may be vaporized by heating to turn into an organic material vapor 152. The crucible 150 may slowly discharge the organic material vapor 152, and the discharged organic material vapor 152 may be sprayed into the upper portion of the standby region S. When the heated upper plate 160 is not situated in the upper portion of the standby region S, the organic material vapor 152 may be deposited on the inner barrier wall 112. The organic material may be deposited to a thickness of several hundreds of micrometers or several millimeters. When the deposited organic material is peeled, it may serve as contamination particles.

According to an embodiment of the present invention, when the upper plate 160 is disposed in the standby region S and is heated to a temperature higher than the boiling point of the organic material by using the plate heating apparatus 162, the organic material vapor 152 may not be deposited on the upper plate 160. A portion of the organic material vapor 152 that fails to be deposited on the upper plate 160 may spread around. Consequently, the upper plate 160 may be prevented from being contaminated by the organic material.

The non-deposited organic material vapor 152 that spreads around may be collected by the cooled lower plate 170 and the cooled lateral plates 175. When there are neither lower plates 170 nor lateral plates 175, the non-deposited organic material vapor 152 may spread all around the second region R2 of the chamber 110, and may contaminate the entire area of the chamber 110.

Due to the cooled lower plate 170 and the cooled lateral plates 175, a temperature difference is generated in the second region R2 of the chamber 110. As a result, a pressure difference is generated between the cooled lower plate 170 and the surrounding area and between the cooled lateral plates 175 and the surrounding areas, the non-deposited organic material vapor 152 moves to the cooled lower plate 170 and the cooled lateral plates 175, and an organic material vapor 152 that contacts the lower plate 170 and the lateral plates 175 cooled to a temperature lower than the freezing point of the organic material is frozen into a solid.

The rail 140 may be heated by the rail heating apparatus 147. If the organic material is deposited on the rail 140, the driving apparatus 145 cannot smoothly move the crucible 150 between the standby region S and the deposition region D. As the rail 140 is also heated to a temperature higher than the boiling point of the organic material, the organic material vapor 152 may not be deposited on the rail 140.

The locations and sizes of the cooled lower plate 170 and the cooled lateral plates 175 may be determined so that the organic material vapor 152 that spreads around due to the upper plate 160 may be collected.

FIG. 4 is a perspective view of an upper plate 160, a lower plate 170, and a lateral plate 175 according to an embodiment of the present invention which may be included in the organic material deposition apparatus 100 of FIGS. 1 and 2.

Referring to FIG. 4, the lower plate 170 may be disposed in the lower portion of the standby region S and also in a part of the lower portion of the deposition region D. In other words, the lower plate 170 may extend from the standby region S to the deposition region D. Even while the crucible 150 is moving in the deposition region D, an organic material vapor may be discharged. Thus, the lower plate 170 may also be disposed under the rail 140 extending between the deposition region D and the standby region S in order to effectively collect the organic material vapor 152.

The upper plate 160 may be disposed in the upper portion of the standby region S.

The lateral plate 175 may be disposed on three lateral sides of the standby region S. The lower plate 170 and the lateral plate 175 may directly contact each other as described above. Alternatively, the lower plate 170 and the lateral plate 175 may be integrally formed in one body. The lateral plate 175 may be integrally formed in one body as illustrated in FIG. 4, or 3 lateral plates 175 may be formed. However, the lateral plate 175 and the lower plate 170 may be cooled by a single plate cooling portion.

The lateral plate 175 and the lower plate 170 may be installed in a chamber such as to be detachable from each other, in order to remove a collected organic material.

Although an upper end of the lateral plate 175 is significantly apart from the upper plate 160 in FIG. 4, this is only an example, and the height of the lateral plate 175 may be determined in consideration of the area of the upper plate 160, the entire space of the chamber, the type of organic material used, and the like. Although the upper end of the lateral plate 175 is located under the upper plate 160 in FIG. 4, the upper end of the lateral plate 175 may be located above the upper plate 160.

Although both the lower plate 170 and the lateral plate 175 are included in the embodiment of FIGS. 1 and 2, only one of the lower plate 170 and the lateral plates 175 may exist in other embodiments. Although the chamber heating apparatus 115, the plate heating apparatus 162, and the plate cooling apparatus 172 are installed in box shapes outside the chamber 110 in the embodiment of FIGS. 1 and 2, this is only an example. As occasion needs, various types of heating devices or various types of cooling devices may be used, and a heating device and a cooling device may exist in various locations according to the types of devices used. For example, the plate heating apparatus 162 may be disposed directly on the upper plate 160. The plate cooling apparatus 172 may be disposed on the lower plate 170 or may be disposed within the chamber 110. The location and shape of the rail heating apparatus 147 illustrated in FIG. 1 are also exemplary, and the rail heating apparatus 147 may exist in the other shapes in the other locations according to the type of heating device used.

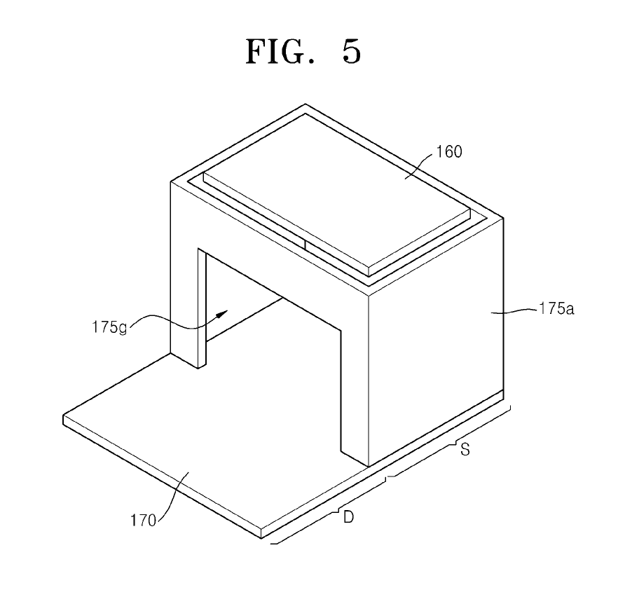

FIG. 5 is a perspective view of an upper plate 160, a lower plate 170, and a lateral plate 175a according to another embodiment of the present invention which may be included in the organic material deposition apparatus 100 illustrated in FIGS. 1 and 2.

Since the upper plate 160 and the lower plate 170 of FIG. 5 are substantially the same as the upper plate 160 and the lower plate 170 of FIG. 4, a detailed description thereof is omitted.

The lateral plate 175a may be disposed on four lateral sides of the standby region S. However, a portion of the lateral plate 175a that is disposed between the standby region S and the deposition region D may include an entrance gate 175g as illustrated in FIG. 5 so that the rail 140 may pass through the entrance gate 175g, and the driving apparatus 145 and the crucible 150 may move through the entrance gate 175g along the rail 140.

As illustrated in FIG. 5, an upper end of the lateral plate 175a may extend up to the level of the upper plate 160. Alternatively, the upper end of the lateral plate 175a may extend to be higher than the upper plate 160.

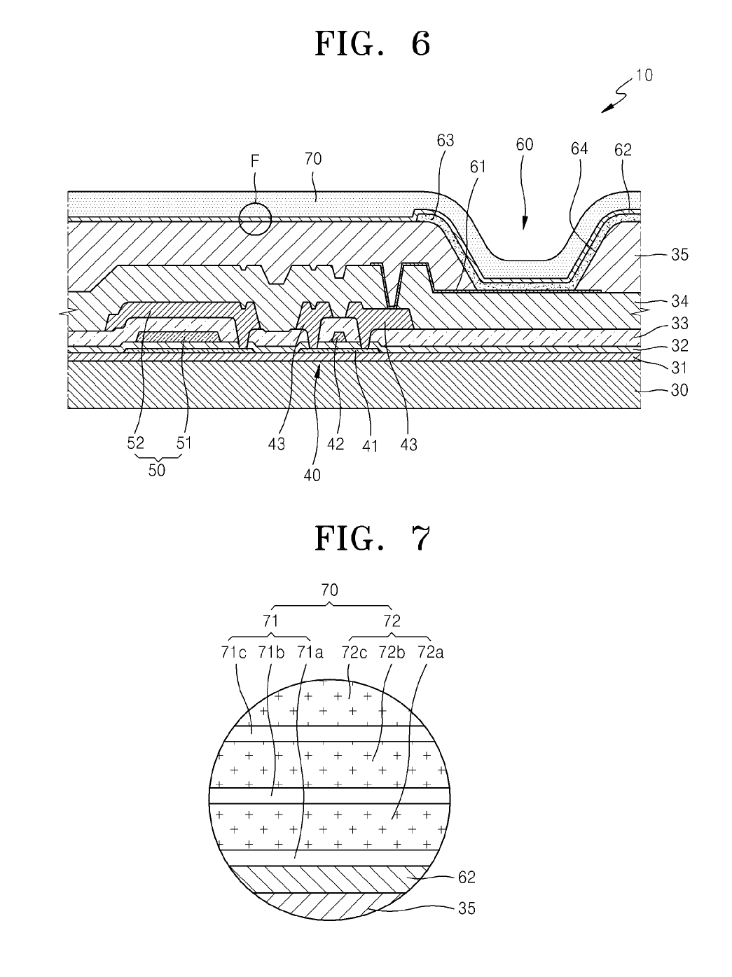

FIG. 6 is a schematic sectional view of an organic light-emitting display apparatus 10 fabricated by using the organic material deposition apparatus 100 of FIG. 1, according to an embodiment of the present invention, and FIG. 7 is a magnified view of a part F of the organic light-emitting display apparatus 10 of FIG. 6.

That is, FIGS. 6 and 7 illustrate the organic light emitting display apparatus 10 fabricated by the organic material deposition apparatus 100.

The organic light emitting display apparatus 10 may be formed on a substrate 30. The substrate 30 may be formed of glass, plastic or metal.

A buffer layer 31 may be formed on the substrate 30. The buffer layer 31 may provide a flat surface to an upper surface of the substrate 30 and may contain an insulation material in order to prevent moisture and foreign matters from penetrating into the substrate 30.

A thin film transistor (TFT) 40, a capacitor 50, and an organic light emitting device 60 may be formed on the buffer layer 31. The TFT 40 may be roughly divided into an active layer 41, a gate electrode 42, and source/drain electrodes 43. The organic light emitting device 60 may include a first electrode 61, a second electrode 62, and an intermediate layer 63. The capacitor 50 may include a first capacitor electrode 51 and a second capacitor electrode 52.

In detail, the active layer 41 may be formed on the upper surface of the buffer layer 31 in a predetermined pattern. The active layer 41 may contain an inorganic semiconductor material, such as silicon, an organic semiconductor material, or an oxide semiconductor material, and may be formed via implantation of a p-type or n-type dopant.

A gate insulating layer 32 may be formed to cover the active layer 41. The gate electrode 42 may be formed on a part of the gate insulating layer 32 that faces the active layer 41. The first capacitor electrode 51 may be formed on the gate insulating layer 32, and may be formed of the same material as the material used to form the gate electrode 42.

An interlayer insulating layer 33 may be formed to cover the gate electrode 42. The source/drain electrodes 43 may be formed on the interlayer insulating layer 33 such as to contact a predetermined part of the active layer 41. The second capacitor electrode 52 may be formed on the interlayer insulating layer 33, and may be formed of the same material as the material used to form the source/drain electrodes 43.

A passivation layer 34 may be formed to cover the source/drain electrodes 43, and an insulating layer (not shown) may be further formed on the passivation layer 34 so as to planarize the TFT 40.

The first electrode 61 may be formed on the passivation layer 34. The first electrode 61 may be electrically connected to one of the source/drain electrodes 43 of the TFT 40. A pixel defining layer 35 may be formed to cover the first electrode 61. An opening 64 may be formed in the pixel defining layer 35, and then the intermediate layer 63, including an organic emission layer, may be formed in a region defined by the opening 64. The second electrode 62 may be formed on the intermediate layer 63.

An encapsulation layer 70 may be formed on the second electrode 62. The encapsulation layer 70 may have a structure where an organic layer and an inorganic layer are stacked alternately.

In particular, the encapsulation layer 70 may include an inorganic layer 71 and an organic layer 72. The inorganic layer 71 may include a plurality of inorganic layers, namely, first, second, and third inorganic layers 71a, 71b, and 71c, and the organic layer 72 may include a plurality of organic layers, namely, first, second, and third organic layers 72a, 72b, and 72c. The first, second, and third organic layers 72a, 72b, and 72c of the organic layer 72 may be formed by using the organic material deposition apparatus 100. In detail, after the substrate 30 having the second electrode 62 and the first inorganic layer 71a formed thereon is disposed within the first region R1 of the chamber 110, the crucible 150 is moved to the deposition region D by the driving apparatus 145. Thus, the first organic layer 72a may be formed. In addition, after the second inorganic layer 71b is formed, the second organic layer 72b may be formed by using the organic material deposition apparatus 100. Moreover, after the third inorganic layer 71c is formed, the third organic layer 72c may be formed by using the organic material deposition apparatus 100.

The present invention is not limited to the formation of the first, second, and third organic layers 72a, 72b, and 72c. In other words, other organic layers included in the organic light emitting display apparatus 10, such as, the passivation layer 34, the pixel defining layer 35, and the intermediate layer 63, may also be formed by using the organic material deposition apparatus 100.

Thin films included in a liquid crystal display (LCD) or various displays other than the organic light emitting display apparatus 10 may also be formed by using the organic material deposition apparatus 100. The present invention is not limited to the thin films for use in these displays, and organic thin films for the other various uses may be formed by using the organic material deposition apparatus 100.

In an organic material deposition apparatus according to an embodiment of the present invention, deposition of an organic material on portions other than a substrate may be reduced or effectively prevented. Moreover, the amount of an organic material used may be reduced, and resources necessary for maintaining the organic material deposition apparatus may be reduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic material deposition apparatus, comprising:
a chamber including a deposition region and a standby region;
a substrate support unit which is accommodated in an upper portion of the chamber and supports the substrate;
a rail disposed inside the chamber, the rail extending from the deposition region to the standby region, the deposition region disposed under the substrate support unit;
a crucible evaporating an organic material;
a driving apparatus which moves the crucible along the rail; an upper plate disposed in an upper portion of the standby region;
a plate heating apparatus heating the upper plate;
a lower plate disposed in a lower portion of the standby region; and
a plate cooling apparatus cooling the lower plate.

2. The organic material deposition apparatus of claim 1, further comprising a lateral plate disposed on at least three lateral sides of the standby region, the plate cooling apparatus cooling the lateral plate.

3. The organic material deposition apparatus of claim 1, wherein the lower plate extends to the deposition region so as to be disposed in at least a part of a lower portion of the deposition region.

4. The organic material deposition apparatus of claim 1, wherein the chamber comprises a chamber barrier wall that separates an upper region, in which the substrate support unit is disposed, from a lower region including the deposition region and the standby region, and the chamber barrier wall comprises an opening portion under the substrate support unit.

5. The organic material deposition apparatus of claim 4, wherein a mask is mounted on a circumference of the opening portion via an o-ring, and a space between the chamber barrier wall and the mask is sealed.

6. The organic material deposition apparatus of claim 4, wherein the chamber further comprises a chamber outer wall that surrounds the upper region and the lower region, and the chamber barrier wall is fixed to the chamber outer wall so that a space between the chamber barrier wall and the chamber outer wall is sealed.

7. The organic material deposition apparatus of claim 6, further comprising a chamber heating apparatus which heats at least one of the chamber outer wall and the chamber barrier wall.

8. The organic material deposition apparatus of claim 1, further comprising a rail heating apparatus which heats the rail.

9. The organic material deposition apparatus of claim 1, wherein the substrate support unit further comprises a substrate cooling apparatus which cools the substrate.

10. The organic material deposition apparatus of claim 1, further comprising a hardening lamp which is moved together with the crucible along the rail.

11. The organic material deposition apparatus of claim 1, wherein the plate heating apparatus increases a temperature of the upper plate to a temperature equal to or higher than a boiling point of the organic material.

12. The organic material deposition apparatus of claim 1, wherein the plate cooling apparatus decreases a temperature of the lower plate to a temperature lower than or equal to a freezing point of the organic material.
